(19) United States
(12) Patent Application Publication
(10) Pub. No.: US 2025/0294870 A1
(43) Pub. Date: Sep. 18, 2025

(54) SEMICONDUCTOR DEVICES

(71) Applicant: SAMSUNG ELECTRONICS CO., LTD., Suwon-si (KR)

(72) Inventors: Inhyun Song, Suwon-si (KR); Jongsu Kim, Suwon-si (KR); Kyungin Choi, Suwon-si (KR); Myunggil Kang, Suwon-si (KR); Ohseong Kwon, Suwon-si (KR); Junggil Yang, Suwon-si (KR); Byeolhae Eom, Suwon-si (KR); Hyumin Yoo, Suwon-si (KR); Chanhyeong Lee, Suwon-si (KR)

(21) Appl. No.: 19/017,087

(22) Filed: Jan. 10, 2025

(30) Foreign Application Priority Data
Mar. 13, 2024 (KR) 10-2024-0035225

(51) Int. Cl. H10D 84/85; H10D 84/01

(52) U.S. Cl. CPC H10D 84/851; H10D 84/0167; H10D 84/017; H10D 84/0177

(57) ABSTRACT

A semiconductor device is provided, the semiconductor device including: a first transistor and a second transistor on a substrate, wherein each of the first transistor and the second transistor includes an active pattern on the substrate, channel layers spaced apart from each other on the active pattern, and a gate dielectric layer and a gate electrode surrounding the channel layers, wherein the gate dielectric layer of the first transistor includes a first work function metal layer and a first work function adjusting layer on the first work function metal layer, and the gate electrode of the second transistor includes a second work function metal layer, the first and second work function metal layers include the same material, and the first work function adjusting layer includes an oxide of the same material, wherein a threshold voltage of the first transistor is lower than a threshold voltage of the second transistor.

### CROSS-REFERENCE TO RELATED APPLICATION(S)

This application claims priority to Korean Patent Application No. 10-2024-0035225, filed on Mar. 13, 2024, the content of which is incorporated herein by reference in its entirety.

### BACKGROUND

As demand for high performance, high speed, and/or multifunctionality of semiconductor devices increases, a degree of integration of semiconductor devices is increasing. In manufacturing fine-patterned semiconductor devices in response to the trend for high integration in semiconductor devices, it is necessary to implement patterns with a fine width or a fine separation distance. In addition, in order to overcome limitations in operating characteristics due to size reductions of a planar metal oxide semiconductor FET (MOSFET), efforts are being conducted to develop semiconductor devices including a FinFET with a three-dimensional channel.

### SUMMARY

An aspect of the present disclosure is to provide a semiconductor device with improved electrical characteristics and reliability.

According to an aspect of the present disclosure, a semiconductor device is provided, the semiconductor device including: a substrate including an active pattern extending in a first direction; channel layers arranged on the active pattern to be spaced apart from each other in a direction perpendicular to an upper surface of the substrate; a gate structure extending in a second direction intersecting the active pattern on the substrate and surrounding the channel layers; and source/drain patterns disposed on both sides of the gate structure, and connected to the channel layers, wherein the gate structure includes a gate dielectric layer on the channel layers, a multilayer work function electrode pattern on the gate dielectric layer, and a filling electrode on the multilayer work function electrode pattern, wherein the multilayer work function electrode pattern includes at least one work function adjusting layer having a higher oxygen concentration than an oxygen concentration of the other layers.

According to an aspect of the present disclosure, a semiconductor device is provided, the semiconductor device including: a first transistor and a second transistor on a substrate, wherein each of the first transistor and the second transistor includes an active pattern on the substrate, channel layers spaced apart from each other on the active pattern in a direction perpendicular to an upper surface of the substrate, and a gate dielectric layer and a gate electrode surrounding the channel layers, and sequentially stacked on the channel layers, wherein the gate dielectric layer of the first transistor includes a first work function metal layer and a first work function adjusting layer on the first work function metal layer, the gate electrode of the second transistor includes a second work function metal layer, the first and second work function metal layers include a same material, and the first work function adjusting layer includes an oxide of the same material, wherein a threshold voltage of the first transistor is lower than a threshold voltage of the second transistor.

According to an aspect of the present disclosure, a semiconductor device is provided, the semiconductor device including: a first transistor and a second transistor on a substrate, wherein each of the first transistor and the second transistor includes an active pattern on the substrate, channel layers spaced apart from each other on the active pattern in a direction perpendicular to an upper surface of the substrate, and a gate dielectric layer and a gate electrode surrounding the channel layers, and sequentially stacked on the channel layers, wherein the gate electrode of each of the first transistor and the second transistor includes a first work function metal layer, a work function adjusting layer on the first work function metal layer, and a second work function metal layer on the work function adjusting layer, the first and second work function metal layers include a same material, and the first work function adjusting layer includes an oxide of the same material, wherein the gate dielectric layer of each of the first transistor and the second transistor includes different dielectric materials, and the first transistor and the second transistor have different threshold voltages.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a plan view illustrating a semiconductor device according to some implementations of the present disclosure;

FIG. 2A illustrates cross-sections of the semiconductor device of FIG. 1 taken along lines I-I′ and II-II′;

FIG. 2B is a partial enlarged view illustrating region Al of the semiconductor device of FIG. 2A;

FIG. 2C illustrates an oxygen concentration distribution in a thickness direction of the gate electrode of FIG. 2B;

FIG. 3A is a cross-sectional view illustrating a semiconductor device according to some implementations of the present disclosure, and FIG. 3B is a partial enlarged view illustrating region A2 of the semiconductor device of FIG. 3A;

FIG. 4A is a cross-sectional view illustrating a semiconductor device according to some implementations of the present disclosure, and FIG. 4B is a partial enlarged view illustrating region A3 of the semiconductor device of FIG. 4A;

FIG. 5A is a cross-sectional view illustrating a semiconductor device according to some implementations of the present disclosure, and FIG. 5B is a partial enlarged view illustrating region A4 of the semiconductor device of FIG. 5A;

FIG. 6 is a plan view illustrating a semiconductor device according to some implementations of the present disclosure;

FIG. 7 is a cross-sectional view of the semiconductor device of FIG. 6 taken along lines III1-III1′ and III2-III2′;

FIG. 8 is a plan view illustrating a semiconductor device according to some implementations of the present disclosure;

FIG. 9 is a cross-sectional view of the semiconductor device of FIG. 8 taken along lines IV1-IV1′, IV2-IV2′, and IV3-IV3′;

FIG. 10 is a cross-sectional view illustrating a semiconductor device according to some implementations of the present disclosure; and

FIGS. 11A to 11H are cross-sectional views for each main process for illustrating a method of manufacturing a semiconductor device according to some implementations of the present disclosure.

### DETAILED DESCRIPTION

Hereinafter, various implementations of the present disclosure will be described in detail with reference to the attached drawings.

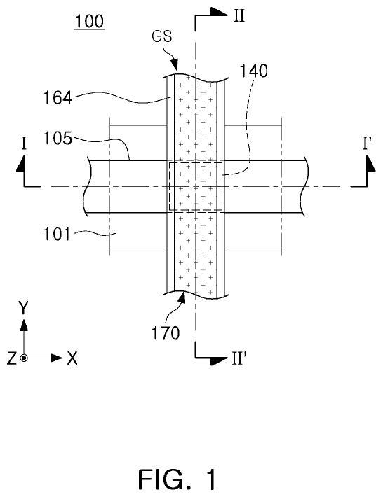

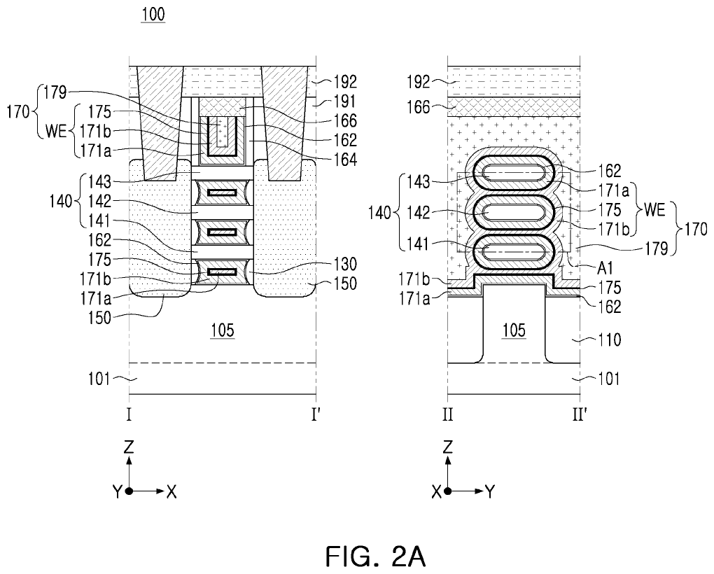

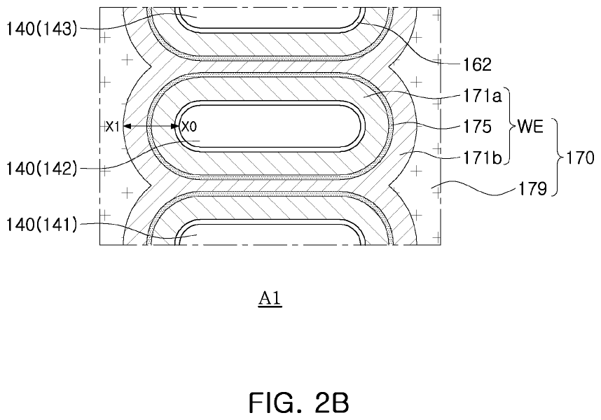

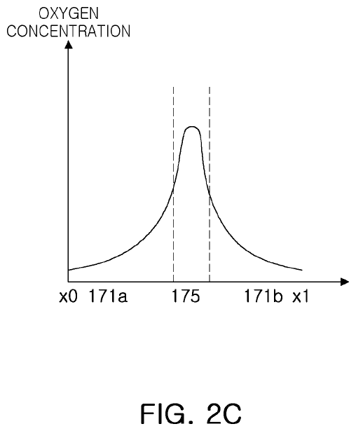

FIG. 1 is a plan view illustrating a semiconductor device according to some implementations of the present disclosure, and FIG. 2A illustrates cross-sections of the semiconductor device of FIG. 1 taken along lines I-I′ and II-II′.

Referring to FIGS. 1 and 2A, a semiconductor device 100 according to some implementations includes a substrate 101 having an active pattern 105, a channel structure 140 disposed on the active pattern 105, a gate structure GS intersecting the active pattern 105, source/drain patterns 150 contacting the channel structure 140, and contact structures 180 connected to the source/drain patterns 150.

In some implementations, the active pattern 105 has a fin shape extending in a first direction (e.g., X-direction) from an upper surface of the substrate 101 and protruding in a third direction (e.g., Z-direction). An upper end of the active pattern 105 may protrude from an upper surface of the device isolation layer 110 to a predetermined height. For example, the substrate 101 may be a semiconductor substrate, such as a silicon substrate or a germanium substrate, or a silicon-on-insulator (SOI) substrate. The device isolation layer 110 may be disposed on the substrate 101 to define the active pattern 105. In some example implementations, the active pattern 105 may be formed in a well region containing impurities. For example, for a p-type transistor, the well region may contain n-type impurities such as phosphorus (P), arsenic (As), or antimony (Sb), and for an n-type transistor, the well region may contain P-type impurities such as boron (B), gallium (Ga), or aluminum (Al).

The device isolation layer 110 may be disposed on the substrate 101 to cover a side surface of the active pattern 105 of the substrate 101. The device isolation layer 110 may include, for example, an oxide film, a nitride film, or a combination thereof. The device isolation layer 110 may be formed by a shallow trench isolation (STI) process. In some example implementations, the device isolation layer 110 may further include a region extending deeper into the substrate 101 (e.g., deep trench isolation (DTI)). The device isolation layer 110 may be formed so that an upper region of the active pattern 105 is exposed. In some example implementations, the device isolation layer 110 may have a curved upper surface with a higher level, more adjacent to the active pattern 105.

In some implementations, the channel structure 140 includes first to third channel layers 141, 142, and 143 spaced apart in a vertical direction (e.g., Z-direction) on the active pattern 105. Each of the first to third channel layers 141, 142, and 143 may include a semiconductor material for providing a channel region. For example, the first to third channel layers 141, 142, and 143 may include at least one of silicon (Si), silicon germanium (SiGe), and germanium (Ge). For example, the first to third channel layers 141, 142, and 143 may be formed of the same material as the substrate 101. The channel structure 140 may have a width equal to or smaller than that of the active pattern 105 in the second direction (e.g., Y-direction), and may have the same or similar width as the gate structure GS in the first direction (e.g., X-direction). In some example implementations, the channel structure 140 has a width smaller than the width of the gate structure GS such that a side surface of the channel structure 140 is located below the gate structure GS in the first direction (e.g., X-direction). In some implementations, the first to third channel layers 141, 142, and 143 are illustrated as three, but the number and shape thereof may vary.

The active pattern 105 may have recessed regions on both sides of the gate structure GS, and source/drain patterns 150 may be formed in the recessed regions through epitaxial regrowth. The source/drain patterns 150 may be connected to both sides of each of the first to third channel layers 141, 142, and 143. The source/drain patterns 150 may include Si, SiGe, or Ge, and depending on the n-type or P-type transistor, the source/drain patterns 150 may have a different material or a different shape, and may have different shapes. For example, in the case of a P-type transistor, the source/drain patterns 150 may include silicon-germanium (SiGe), and may be doped with P-type impurities (e.g., boron (B), indium (In), gallium (Ga). A cross-section (Y-Z cross-section) of the source/drain patterns 150 may have a pentagonal shape. In contrast, in the case of an n-type transistor, the source/drain patterns 150 may include silicon, and may be doped with N-type impurities (e.g., phosphorus (P), nitrogen (N), arsenic (As), antimony (Sb)). The cross-section (Y-Z cross-section) of the source/drain patterns 150 may be hexagonal or polygonal with gentle angles.

In some implementations, the gate structure GS may intersect the active pattern 105 and the channel structure 140 and extend in a second direction, for example, the second direction (e.g., Y-direction). Channel regions of transistors may be formed in the channel structure 140 intersecting the gate electrode 170 of the gate structure GS. Specifically, the gate structure GS may be configured to surround the first to third channel layers 141, 142, and 143, respectively. In this context, the semiconductor device 100 may be a gate-all-around type field effect transistor.

The gate structure GS includes a gate electrode 170, gate dielectric layers 162 between the gate electrode 170 and the channel structure 140, and gate spacers 164 on side surfaces of the gate electrode 170. The gate structure 170 may further include gate spacers 164 disposed on the side surfaces of the gate electrode 175 and a gate capping layer 166 disposed on the gate electrode 170.

The gate dielectric layers 162 may be disposed between the active pattern 105 and the gate electrode 170 and between the channel structure 140 and the gate electrode 170. In some example implementations, the gate dielectric layers 162 may be disposed to surround all surfaces of gate electrode 170 except the top surface thereof. The gate dielectric layers 162 may extend between the gate electrode 170 and the gate spacers 164, but the present disclosure is not limited thereto. The gate dielectric layers 162 may include oxide, nitride, or a high-k material. The high-K material may refer to a dielectric material having a higher dielectric constant than a silicon oxide film (SiO₂). The high-K material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓOy), hafnium aluminum oxide (HfAlₓO_{y}), and praseodymium oxide (Pr₂O₃). In some implementations, the gate dielectric layers 162 may have a multilayer structure.

The gate spacers 164 may be disposed on both side surfaces of the gate electrode 170. The gate spacers 164 may insulate the source/drain patterns 150 and the gate electrode 170. In some example implementations, the gate spacers 164 may have a multilayer structure. The gate spacers 164 may be formed of oxide, nitride, and oxynitride, and in particular, may be formed of a low dielectric constant film.

The gate electrode 170 may fill a space between the first to third channel layers 141, 142, and 143 on the active pattern 105, and may extend on the third channel layer 143, which is the uppermost channel layer. The gate electrode 170 includes a multilayer work function electrode pattern WE disposed on the gate dielectric layers 162, and a filling electrode 179 on the multilayer work function electrode pattern WE. The multilayer work function electrode pattern WE employed in some implementations may have a multilayer structure for controlling the threshold voltage. In a cross-section in an extension direction (II-II′) of the gate electrode 170 in FIG. 2A, the multilayer work function electrode pattern WE may be disposed to surround each of the first to third channel layers 141, 142, and 143. The multilayer work function electrode pattern WE may be additionally disposed on the upper surfaces of the active pattern 105 and the device isolation layer 110.

The multilayer work function electrode pattern WE includes a work function adjusting layer 175 having a higher oxygen concentration than an oxygen concentration of the other layers 171a and 171b. FIG. 2B is a partial enlarged view of portion A1 of FIG. 2A.

Referring to FIGS. 2A and 2B, the multilayer work function electrode pattern WE employed in some implementations may include a first work function metal layer 171a and a second work function metal layer 171b, and the work function adjusting layer 175 may be disposed between the first and second work function metal layers 171a and 171b. The first and second work function metal layers 171a and 171b may be disposed relatively conformally. However, the second work function metal layer 171b may have a different thickness between the channel layers 141, 142, and 143 depending on the remaining space.

In some implementations, the first and second work function metal layers 171a and 171b may include the same material, and the work function adjusting layer 175 may include an oxide of the same material. The work function adjusting layer 175 may be an oxide layer obtained by applying surface oxidation treatment (e.g., surface heat treatment in an oxygen atmosphere) to the first work function metal layer 171a. The work function adjusting layer 175 can be confirmed by an oxygen concentration distribution. This distribution can be confirmed through various atomic analysis methods such as Scanning Transmission Electron Microscope (STEM)-Electron Energy Loss Spectroscopy (EELS) and Energy Dispersive Spectroscopy (STEM-EDS).

FIG. 2C illustrates an oxygen concentration distribution in a thickness direction (x0-x1) of the gate electrode 170 of FIG. 2B. As illustrated in FIG. 2C, the work function adjusting layer 175 may have a higher oxygen concentration than an oxygen concentration of the first and second work function metal layers 171a and 171b, and may have a relatively high oxygen concentration distribution as oxygen diffuses into a region adjacent to the first and second work function metal layers 171a and 171b depending on heat treatment conditions.

In some example implementations, the first and second work function metal layers 171a and 171b may include TiN. The work function adjusting layer 175 may include TiON. For example, the work function adjusting layer 175 may have an oxygen concentration of 1 atom % or more.

As described above, a threshold voltage can be adjusted by changing elements in some areas of the multilayer work function electrode pattern WE. Specifically, the threshold voltage may be further lowered by introducing the work function adjusting layer 175 with a relatively high oxygen concentration, and by using the work function adjusting layer 175, transistors (e.g., p-type transistors) with more various different threshold voltages can be formed on the same substrate.

In some implementations, when the same material of the first and second work function metal layers 171a and 171b is an oxide, the work function adjusting layer 175 may include a compound having a higher oxygen concentration than that of an oxide of the same material.

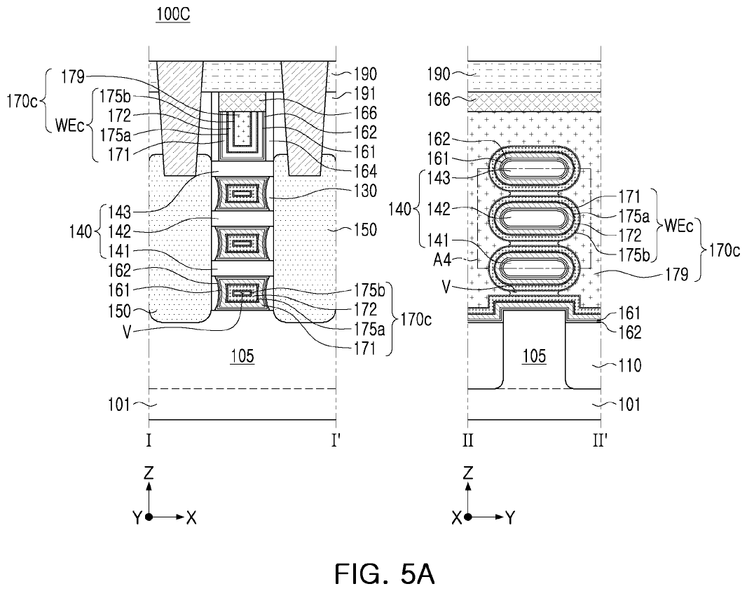

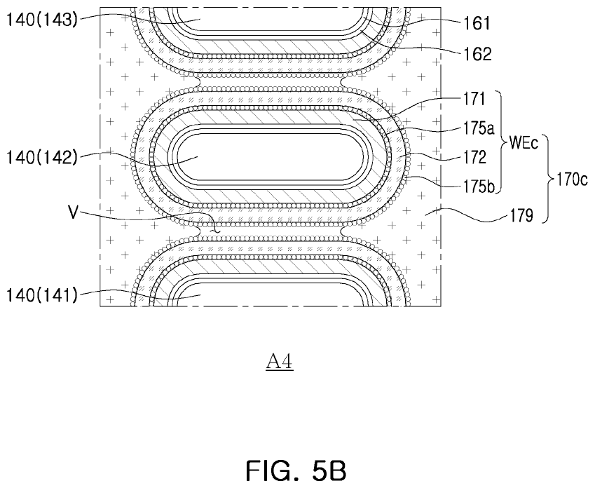

In some example implementations, the first and second work function metal layers 171a and 171b may include different materials. For example, the first and second work function metal layers 171a and 171b may include TiAlC, TiAlN, WN, or MoN in addition to TiN. In some implementations, the second work function metal layer 171b may include a material with a lower work function than the first work function metal layer 171a. For example, the first work function metal layer 171a may include TiN, and the second work function metal layer 171b may include a material containing aluminum (Al), for example, TiAlC or TiAlN (e.g., see FIGS. 5A and 5B).

In some implementations, the second work function metal layer 171b may be disposed on the work function adjusting layer 175, surround the first to third channel layers 141, 142, and 143 in a second direction (e.g., Y-direction), and formed to fill the remaining space therebetween. As described above, the second work function metal layer 171b may have a small thickness between the channel layers 141, 142, and 143 depending on the remaining space. In some example implementations, when the remaining space between the first to third channel layers 141, 142, and 143 is narrower, the second work function metal layer 171b may not be interposed between the first to third channel layers 141, 142, and 143.

The filling electrode 179 may cover the active pattern 105 on which the multilayer work function electrode pattern WE is formed and the channel structure 140 and extend in a second direction (e.g., Y-direction) (see FIG. 2B). For example, the filling electrode 179 may be provided on both sidewalls and the upper surfaces of the active pattern 105 and the channel structure 140 in the second direction. For example, the filling electrode 179 may include a metal material such as tungsten (W) or molybdenum (Mo), or a semiconductor material such as doped polysilicon.

In some implementations, the filling electrode 179 may not be provided in the space between the first to third channel layers 141, 142, and 143. In some example implementations, when the remaining space between the first to third channel layers 141, 142, and 143 is sufficient, the second work function metal layer 171b may be relatively conformally interposed between the first to third channel layers 141, 142, and 143, and the filling electrode 179 may be disposed in some spaces between the first to third channel layers 141, 142, and 143.

The internal spacers 130 may be disposed on both side surfaces of the gate electrode 170 in the second direction between the channel layers 141, 142, and 143. The gate electrode 170 may be stably spaced apart from the source/drain patterns 150 by the inner spacers 130, and thus electrically separated. The internal spacers 130 may have a shape in which side surfaces thereof, facing the gate electrode 170 is convexly rounded inwardly toward the gate electrode 170, but the present disclosure is not limited thereto. The internal spacers 130 may be formed of oxide, nitride, and oxynitride, and in particular, may be formed of a low dielectric constant film. However, in some example implementations, the internal spacers 130 may be omitted.

In some implementations, a first interlayer insulating layer 191 may be disposed on the substrate 101. The first interlayer insulating layer 191 may cover the gate spacers 164 and source/drain patterns 150. An upper surface of the first interlayer insulating layer 191 may be substantially coplanar with an upper surface of the gate cap layer 166 and an upper surface of each gate spacer 164. A second interlayer insulating layer 192 covering the gate cap layer 166 may be disposed on the first interlayer insulating layer 191. For example, the first and second interlayer insulating layers 191 and 192 may include silicon oxide.

The contact structures 180 may penetrate the first and second interlayer insulating layers 191 and 192 and be connected to the source/drain patterns 150, and may apply an electrical signal to the source/drain patterns 150. The contact structures 180 may have inclined side surfaces of which a width of a lower portion thereof is narrower than a width of an upper portion thereof depending on an aspect ratio, but the present disclosure is not limited thereto. The contact structures 180 may extend from above, for example, further downwardly of a lower surface of the third channel layer 143. The contact structures 180 may include a metal silicide layer located at a lower end including the lower surface, and may further include a barrier layer disposed on an upper surface and sidewalls of the metal silicide layer. For example, the barrier layer may include a metal nitride, such as titanium nitride (TiN), tantalum nitride (TaN), or tungsten nitride (WN). The contact structures 180 may include a metal material such as aluminum (Al), tungsten (W), or molybdenum (Mo). In some example implementations, the number and dispositional form of conductive layers forming the contact structures 180 may vary.

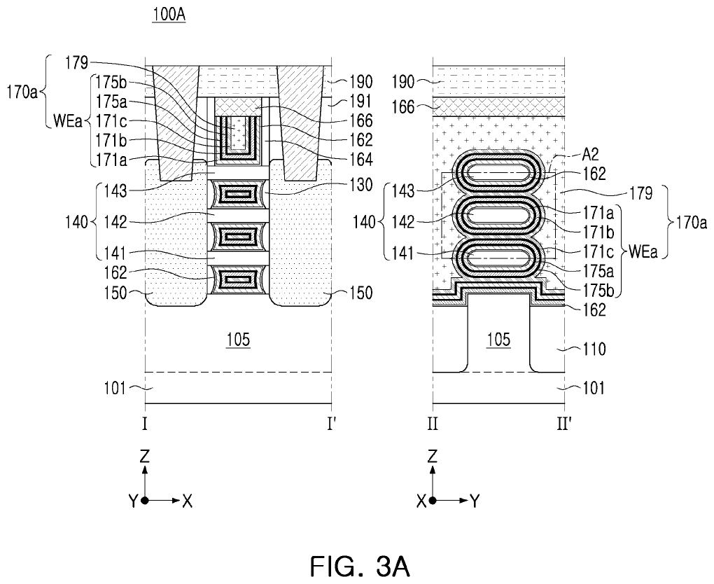

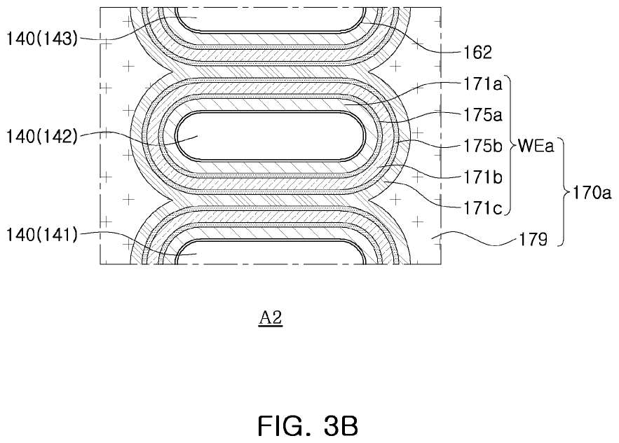

FIG. 3A is a cross-sectional view illustrating a semiconductor device according to some implementations of the present disclosure, and FIG. 3B is a partial enlarged view illustrating region A2 of the semiconductor device of FIG. 3A.

Referring to FIGS. 3A and 3B, a semiconductor device 100A may be understood to be similar to the semiconductor device 100A shown in FIGS. 1 to 2C, except that a multilayer work function electrode pattern WEa has a multilayer structure including three work function metal layers 171a, 171b, and 171c and two work function adjusting layers 175a and 175b. In addition, unless otherwise stated, the components of some implementations may be understood by referring to the description of the same or similar components of the semiconductor device 100 shown in FIGS. 1 to 2C.

The multilayer work function electrode pattern WEa employed in some implementations includes first to third work function metal layers 171a, 171b, and 171c, a first work function adjusting layer 175a disposed between the first and second work function metal layers 171a and 171b, and a second work function adjusting layer 175b disposed between the second and third work function metal layers 171b and 171c.

The first work function adjusting layer 175a may be an oxide layer formed by oxidation treatment on the surface of the first work function metal layer 171a, and similarly thereto, the second work function adjusting layer 175b may be an oxide layer obtained by applying surface oxidation treatment to the second work function metal layer 171b.

In some implementations, the first and second work function metal layers 171a and 171b may include the same material, and the first and second work function adjusting layers 175a and 175b may be an oxide of the same material. In addition, the third work function metal layer 171c may include the same material as that of the first and second work function metal layers 171a and 171b.

For example, the first to third work function metal layers 171a, 171b, and 171c may include TiN. The first and second work function adjusting layers 175a and 175b may include TiON. For example, the first and second work function adjustment layers 175a and 175b may have an oxygen concentration of 1 atom % or more.

In some example implementations, one of the first and second work function adjusting layers 175a and 175b may be a different layer from the other thereof. For example, one of the first and second work function adjustment layers 175a and 175b may be a layer containing fluorine. In a specific example, the first work function adjusting layer 175a may include TiON, and the second work function adjusting layer 175b may include TiFN.

In some example implementations, at least one of the first to third work function metal layers 171a, 171b, and 171c may include a material different from the other layers. For example, the first and second work function metal layers 171a and 171b may include TiN, and the third work function metal layer 171c may include TiAlC, TiAlN, WN, or MoN.

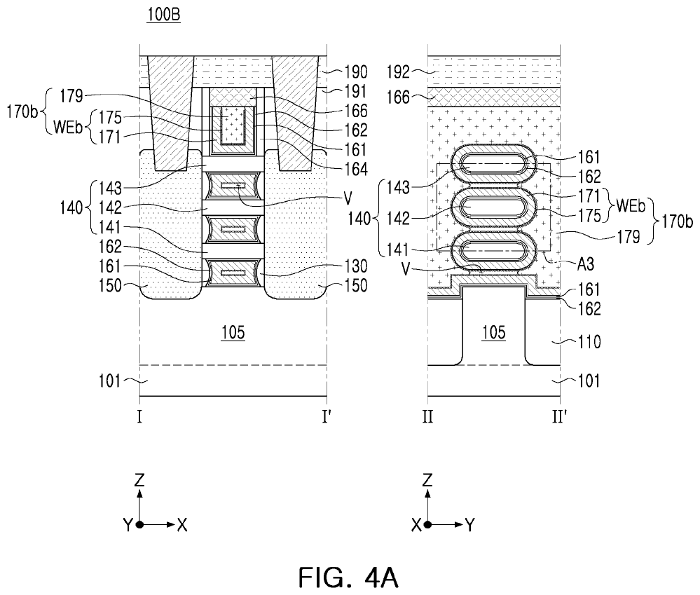

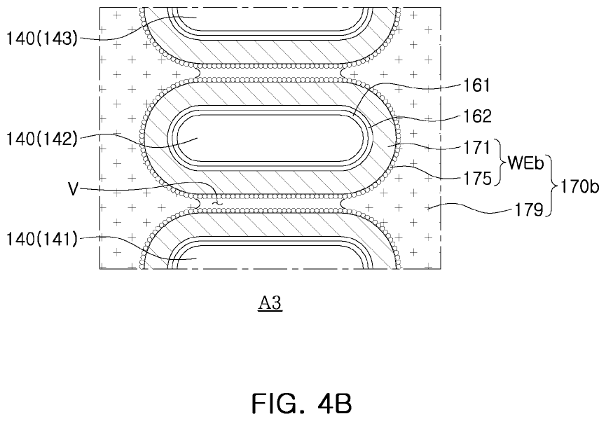

FIG. 4A is a cross-sectional view illustrating a semiconductor device according to some implementations of the present disclosure, and FIG. 4B is a partial enlarged view illustrating region A3 of the semiconductor device of FIG. 4A.

Referring to FIGS. 4A and 4B, a semiconductor device 100B may be understood to be similar to the semiconductor device 100A shown in FIGS. 1 to 2C, except that a multilayer work function electrode pattern WEb has a two-layer structure including one work function metal layer 171 and a work function adjusting layer 175 on the work function metal layer, voids V exist between the channel layers 141, 142, and 143, and an interfacial insulating layer 161 is further included.

In addition, unless otherwise stated, the components of some implementations may be understood by referring to the description of the same or similar components of the semiconductor device 100 shown in FIGS. 1 to 2C.

The multilayer work function electrode pattern WEb employed in some implementations may have a dual-layer structure including one work function metal layer 171 and a work function adjusting layer 175 on the work function metal layer 171. The work function adjusting layer 175 may be an oxide layer obtained by applying oxidation treatment to the surface of the work function metal layer 171. For example, the work function metal layer 171 may include TiN, and the work function adjusting layer 175 may include TiON. In some implementations, a filling electrode 179 may be formed on the work function adjusting layer 175.

In some implementations, the filling electrode 179 may be provided in some spaces between the first to third channel layers 141, 142, and 143. Some spaces between the first to third channel layers 141, 142, and 143 may remain as voids V, not filled with the filling electrode 179.

In some implementations, an interfacial insulating layer 161 may be additionally formed between each gate dielectric layer 162 and the channel layers 141, 142, and 143. For example, the interfacial insulating layer 161 may include silicon oxide or silicon oxynitride.

FIG. 5A is a cross-sectional view illustrating a semiconductor device according to some implementations of the present disclosure, and FIG. 5B is a partial enlarged view illustrating region A4 of the semiconductor device of FIG. 5A.

Referring to FIGS. 5A and 5B, a semiconductor device 100C may be understood to be similar to the semiconductor device 100A shown in FIGS. 1 to 2C, except that a multilayer work function electrode pattern WEc has a multilayer structure including two work function adjusting layers 175a and 175b, two work function metal layers 171 and 172 include different materials, a void V exists between the channel layers 141, 142, and 143, and an interfacial insulating layer 161 is further included. In addition, unless otherwise stated, the components of some implementations may be understood by referring to the description of the same or similar components of the semiconductor device 100 shown in FIGS. 1 to 2C.

The multilayer work function electrode pattern WEc employed in some implementations may include first and second work function metal layers 171 and 172 formed of different materials, a first work function adjusting layer 175a on the first work function metal layer 171, and a second work function adjusting layer 175b between the first and second work function metal layers 171 and 172.

In some implementations, the first and second work function metal layers 171 and 172 may include different materials. For example, the first work function metal layer 171 may include TiN, and the second work function metal layers 172 may include TiAlC, TiAlN, WN, or MoN.

The first work function adjusting layer 175a may be an oxide layer formed by oxidation treatment on the surface of the first work function metal layer 171, and similarly thereto, the second work function adjusting layer 175b may be an oxide layer obtained by applying surface oxidation treatment to the second work function metal layer 172.

For example, the first work function metal layer 171 may include TiN, and the first work function adjusting layer 175a may include TiON. The second work function metal layers 172 may include TiAlN, and the second work function adjusting layer 175a may include TiAlON. In some example implementations, one of the first and second work function adjusting layers 175a and 175b may be a fluorine-containing layer that has been fluorinated. In a specific example, the second work function adjusting layer 175b may include TiAlFN.

In some implementations, a filling electrode 179 may be formed on the second work function adjusting layer 175b. Similar to the previous implementations, the filling electrode 179 may be partially provided in the space between the first to third channel layers 141, 142, and 143. Some spaces between the first to third channel layers 141, 142, and 143 may remain as voids V, not filled with the filling electrode 179. In addition, the semiconductor device 100C according to some implementations may further include an interfacial insulating layer 161 between each gate dielectric layer 162 and the channel layers 141, 142, and 143. For example, the interfacial insulating layer 161 may include silicon oxide or silicon oxynitride.

The method for adjusting the threshold voltage using surface oxidation treatment according to some implementations may easily implement a semiconductor device having transistors driven by different threshold voltages.

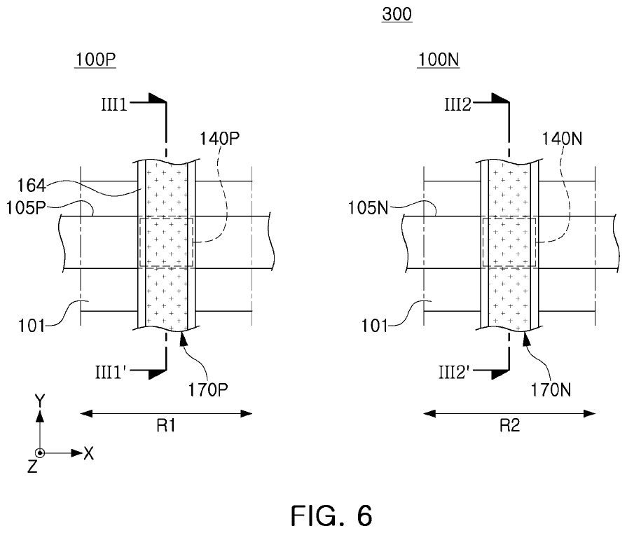

FIG. 6 is a plan view illustrating a semiconductor device according to some implementations of the present disclosure, and FIG. 7 is a cross-sectional view of the semiconductor device of FIG. 6 taken along lines III1-III1′ and III2-III2′.

Referring to FIGS. 6 and 7, a semiconductor device 300 according to some implementations includes P-type and n-type transistors 100P and 100N respectively disposed on the first and second regions R1 and R2 of one substrate 101.

The first and second regions R1 and R2 of the substrate 101 may be adjacent to or spaced apart from each other, and the P-type and n-type transistors 100P and 100N may have a gate all-around structure having a structure similar to that of the previously described implementations, and include an active pattern 105 of different conductivity-types and a source/drain pattern 150 of different conductivity types.

In some implementations, the P-type and n-type transistors 100P and 100N may include first and second gate electrodes 170P and 170N of different structures, respectively.

The first gate electrode 170P includes a first multilayer work function electrode pattern WE_P and a filling electrode 179, similar to the structure illustrated in FIGS. 2A and 2B. The first multilayer work function electrode pattern introduced into the first gate electrode 170P includes a first work function metal layer 171a, a second work function metal layer 171b, and a first work function adjusting layer 175P disposed between the first and second work function metal layers 171a and 171b. In some implementations, the first and second work function metal layers 171a and 171b may include the same first material, and the first work function adjusting layer 175P may include an oxide of the same first material. The first work function adjusting layer 175P may be an oxide layer obtained by applying surface oxidation treatment to the first work function metal layer 171a. For example, the first and second work function metal layers 171a and 171b may include TiN. The first work function adjusting layer 175P may include TiON.

The second gate electrode 170N includes a second multilayer work function electrode pattern WE_N and a filling electrode 179. The second multilayer work function electrode pattern WE_N introduced into the second gate electrode 170N a third work function metal layer 176 and a second work function adjusting layer 175N on the third work function metal layer 176. In some implementations, the third work function metal layer 176 may include a second material different from the first and second work function metal layers 171a and 171b, and the second work function adjusting layer 175 may include an oxide of the same second material. The second work function adjusting layer 175N may be an oxide layer obtained by applying surface oxidation treatment to the third work function metal layer 176. This surface oxidation treatment process may be performed simultaneously in the first and second regions R1 and R2.

In some example implementations, the second material of the third work function metal layer 175 may be a material with a lower work function than the first material of the first and second work function metal layers 171a and 171b. For example, when the first and second work function metal layers 171a and 171b include TiN, the third work function metal layer 176 may include a material containing aluminum (Al), for example, TiAlC or TiAlN. The second work function adjusting layer 175N may include TiAlOC or TiAlON.

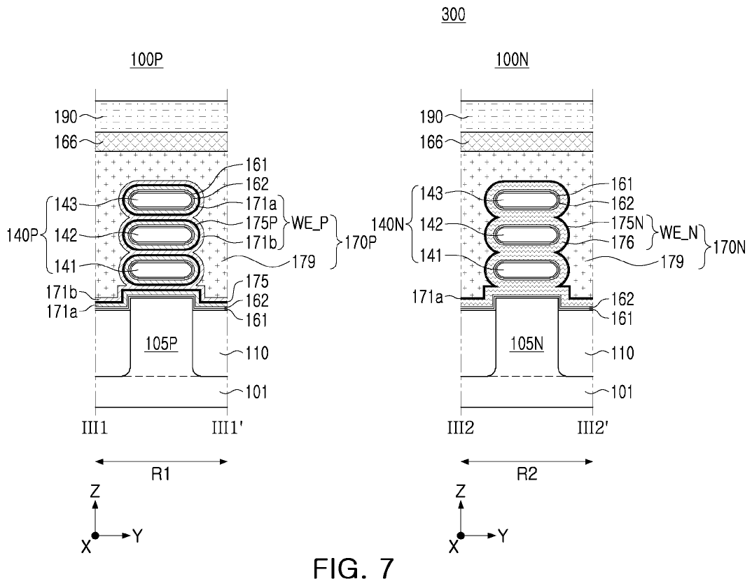

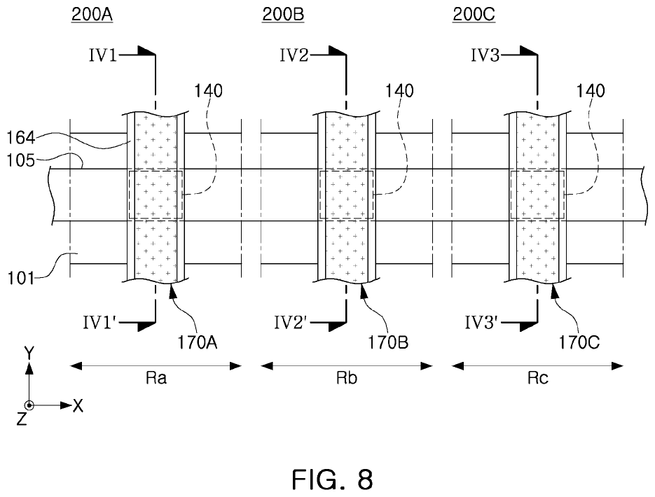

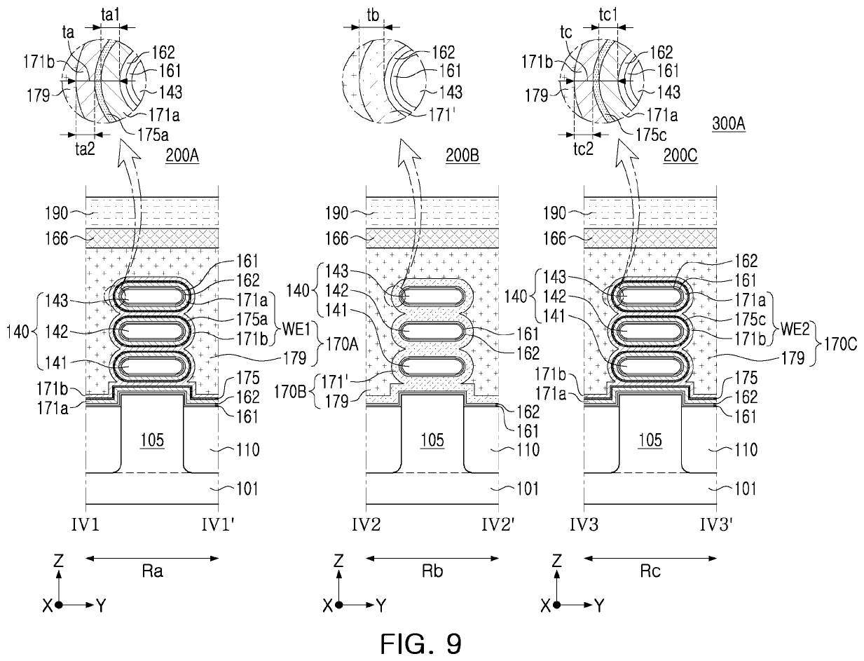

FIG. 8 is a plan view illustrating a semiconductor device according to some implementations of the present disclosure, and FIG. 9 is a cross-sectional view of the semiconductor device of FIG. 9 taken along lines IV1-IV1′, IV2-IV2′, and IV3-IV3′.

Referring to FIGS. 8 and 9, a semiconductor device 300A according to some implementations includes first to third transistors 200A, 200B, and 200C respectively disposed on first to third regions Ra, Rb, and Rc of one substrate 101, and having different threshold voltages.

The first to third regions Ra, Rb, and Rc of the substrate 101 may be adjacent to or spaced apart from each other. Each of the first to third transistors 200A, 200B, and 200C may be a gate all-around transistor having a structure similar to the previously described implementations. In some implementations, the first to third transistors 200A, 200B, and 200C may include first to third gate electrodes 170A, 170B, and 170C of different structures. The first to third transistors 200A, 200B, and 200C including the first to third gate electrodes 170A, 170B, and 170C, respectively, may be transistors driven by different threshold voltages, and may form the same or different circuits within the semiconductor device 300A formed on one substrate 101. For example, when the first to third transistors 200A, 200B, and 200C are P-type transistors, the first transistor 200A in the first region Ra may have the lowest threshold voltage (or operating voltage), and the third transistor 200C in the third region Rc may have the highest threshold voltage (or operating voltage).

In some implementations, the first to third transistors 200A, 200B, and 200C may have the same or similar structures except for the gate electrodes 170A, 170B, and 170C. For example, the first to third transistors 200A, 200B, and 200C may commonly include an active pattern 105 and first to third channel layers 141, 142, and 143, formed through the same process, and as a gate insulation structure, may include an interfacial insulating layer 161 and a gate dielectric layer 162, sequentially formed.

Threshold voltages of the first to third transistors 200A, 200B, and 200C may be implemented differently by designing the first to third gate electrodes 170A, 170B, and 170C differently. In some implementations, the threshold voltage may be adjusted using surface treatment of the work function metal layer 171a.

First, the second gate electrode 170B of the second transistor 200B includes a work function metal layer 171′ and a filling electrode 179 on the work function metal layer 171′. The work function metal layer 171 may have a second thickness (tb). In some implementations, the work function metal layer 171′ may include TiN. The present disclosure is not limited thereto, and in other example implementations, the work function metal layer 171′ may include TiAlC or TiAlN.

The first gate electrode 170A of the first transistor 200A includes a first multilayer work function electrode pattern WE1 and a filling electrode 179. The first multilayer work function electrode pattern WE1 may include a first work function adjusting layer 175A obtained by surface oxidation treatment to lower the threshold voltage (cf., threshold voltage of the second transistor 200B). The first multilayer work function electrode pattern WE1 employed in some implementations may correspond to the multilayer work function electrode pattern WE described in FIGS. 2A to 2C.

The first multilayer work function electrode pattern WE1 may include a first work function metal layer 171a and a second work function metal layer 171b, and the first work function adjusting layer 175A may be disposed between the first and second work function metal layers 171a and 171b. In some implementations, the first and second work function metal layers 171a and 171b may include the same material, and the first work function adjusting layer 175A may include an oxide of the same material. The first work function adjusting layer 175A may be an oxide layer obtained by applying surface oxidation treatment (e.g., surface heat treatment in an oxygen atmosphere) to the first work function metal layer 171a. In some example implementations, the first and second work function metal layers 171a and 171b may include the same material as the work function metal layer 171′ of the second gate electrode 170B. For example, the first and second work function metal layers 171a and 171b may include TiN. The first work function adjusting layer 175A may include TiON.

Similarly, the third gate electrode 170C of the third transistor 200C includes a second multilayer work function electrode pattern WE2 and a filling electrode 179. The second multilayer work function electrode pattern WE2 may include a second work function adjusting layer 175B containing boron (B) and/or carbon (C) to increase the threshold voltage (cf., threshold voltage of the second transistor 200B).

The second multilayer work function electrode pattern includes a first work function metal layer 171a and a second work function metal layer 171b, and the second work function adjusting layer 175C may be disposed between the first and second work function metal layers 171a and 171b. In some implementations, the first and second work function metal layers 171a and 171b may include the same material, and the second work function adjusting layer 175C may include an oxide of the same material. The second work function adjusting layer 175C may be obtained by heat treating the surface of the first work function metal layer 171a in a boron and/or carbon atmosphere. In some example implementations, the first and second work function metal layers 171a and 171b may include the same material as the work function metal layer 171′ of the second gate electrode 170B. For example, the first and second work function metal layers 171a and 171b may include TiN. The second work function adjusting layer 175C may include TiBN, TiCN, or TiBCN. The threshold voltage may vary depending on the elements added by surface treatment. For example, the second work function adjusting layer 175C containing boron (B) may be changed to a higher threshold voltage than the second work function adjusting layer 175C containing carbon (C).

In some example implementations, the first to third gate electrodes 170A, 170B, and 170C may be manufactured by a simplified process. A first work function metal layer 171a is formed in first to third regions Ra, Rb, and Rc using the same material. Next, a surface of the first work function metal layer 171a may be selectively oxidized only in the first region Ra to form a first work function adjusting layer 175A containing oxygen, and then the surface of the first work function metal layer 171a may be selectively boronized or carbonized to form a second work function adjusting layer 175B. Next, a second work function metal layer 171b may be formed in the first to third regions Ra, Rb, and Rc.

In this case, in the first and third regions Ra and Rc, the thicknesses ta1 and tc1 of the first work function metal layer 171a may be substantially equal to each other, and thicknesses ta2 and tc2 of the second work function metal layer 171b may be substantially equal to each other. Although the difference may be somewhat changed by the surface treatment, the overall thickness ta and tc of the first and second multilayer work function electrode patterns WE1 and WE2 may be substantially the same, and the thickness may be substantially equal or similar to the thickness tb of the work function metal layer 171′.

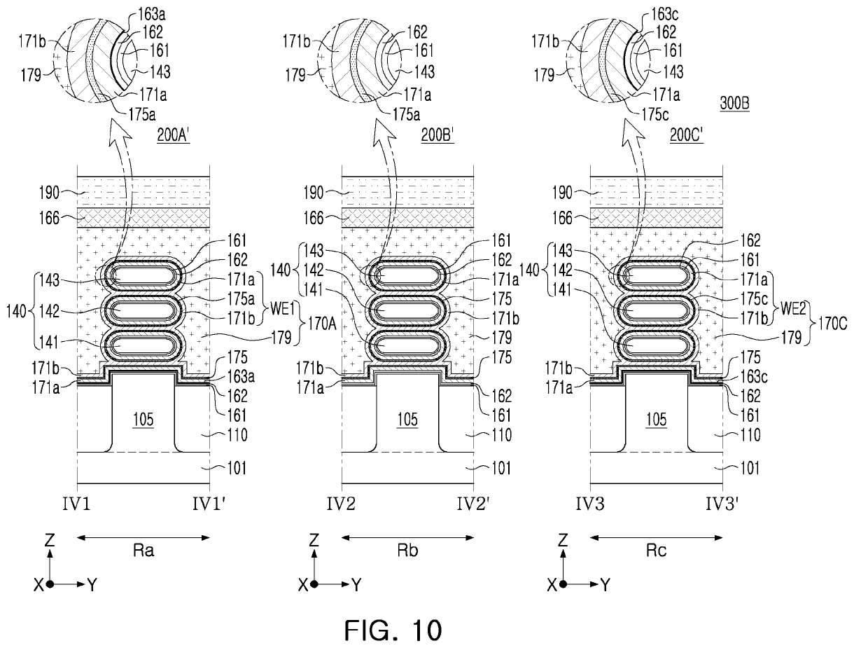

FIG. 10 is a cross-sectional view illustrating a semiconductor device according to some implementations of the present disclosure.

Referring to FIG. 10, a semiconductor device 300B according to some implementations includes first to third transistors 200A′, 200B′, and 200C′ respectively disposed on first to third regions Ra, Rb, and Rc of one substrate 101, and having different threshold voltages.

The first to third regions Ra, Rb, and Rc of the substrate 101 may be adjacent to or spaced apart from each other. Each of the first to third transistors 200A′, 200B′, and 200C′ may be a gate all-around transistor having a structure similar to the previously described implementations. In some implementations, the first to third transistors 200A′, 200B′, and 200C′ may include the same gate electrodes 170, but have different gate dielectric layers, so that threshold voltages of the first to third transistors 200A′, 200B′, and 200C′ may be adjusted differently.

For example, when the first to third transistors 200A′, 200B′, and 200C′ are P-type transistors, based on an absolute value, the first transistor 200A′ in the first region Ra may have the smallest threshold voltage (or operating voltage), and the third transistor 200C in the third region Rc may have the largest threshold voltage (or operating voltage).

The gate electrodes 170 of the first to third transistors 200A′, 200B′, and 200C′ include multilayer work function electrode patterns 171a, 175, and 171b and a filling electrode 179. The multilayer work function electrode pattern employed in some implementations may have a structure similar to the multilayer work function electrode pattern described in FIGS. 2A to 2C. The multilayer work function electrode pattern includes a first work function metal layer 171a and a second work function metal layer 171b, and includes a work function adjusting layer 175a between the first and second work function metal layers 171a and 171b. In some implementations, the first and second work function metal layers 171a and 171b may include the same material, and the first work function adjusting layer 175a may include an oxide of the same material. For example, the first and second work function metal layers 171a and 171b may include TiN. The work function adjusting layer 175 may include TiON.

First, the second transistor 200B′ includes an interfacial insulating layer 161 on the first to third channel layers 141, 142, and 143, and a gate dielectric layer 162 having a high dielectric constant on the interfacial insulating layer 161. The threshold voltage of the first and third transistors 200A′ and 200C′ may be adjusted by dipole treatment on the gate dielectric layer 162.

The first transistor 200A′ may have a high threshold voltage by using a first dipole layer 163a such as aluminum oxide (AlO) on the gate dielectric layer 162 of the first transistor 200A′. Similarly, the third transistor 200C′ may have a high threshold voltage by using a second dipole layer 163c such as lanthanum oxide (LaO) on the gate dielectric layer 162 of the third transistor 200C′. In some implementations, the first to third transistors 200A′, 200B′, and 200C′ are illustrated as having the same multilayer work function electrode pattern, but the multilayer work function electrode pattern may be introduced only in some transistors so that the threshold voltage of the first and third transistors 200A′, 200B′, and 200C′ may also be more variously changed.

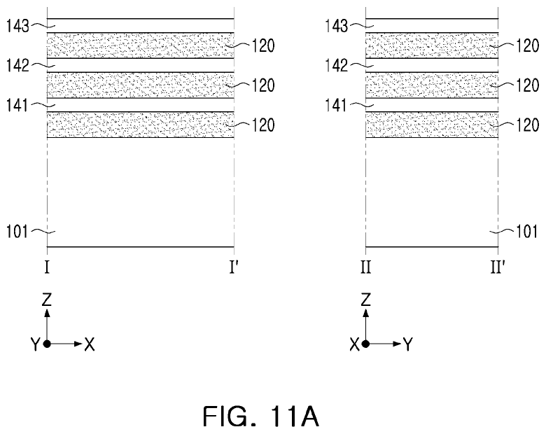

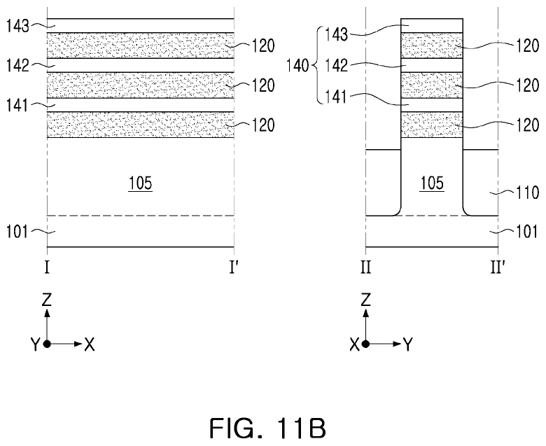

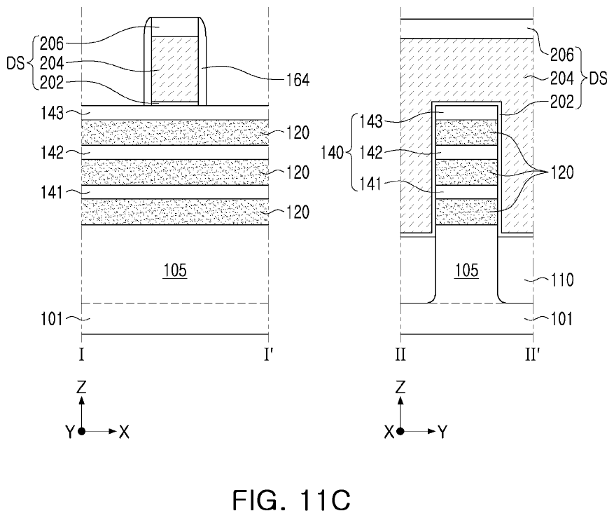

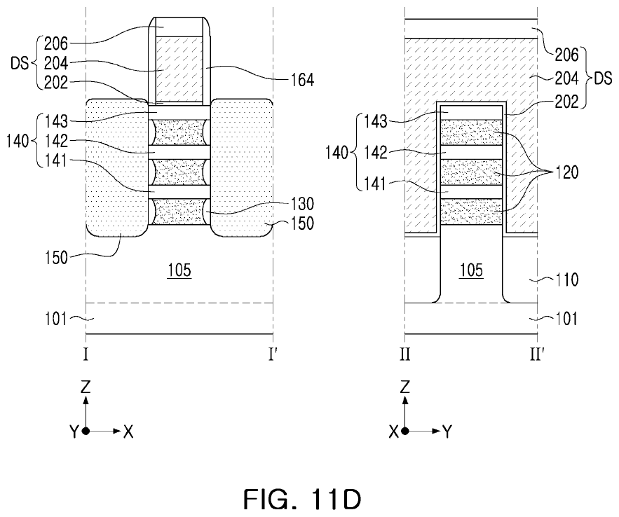

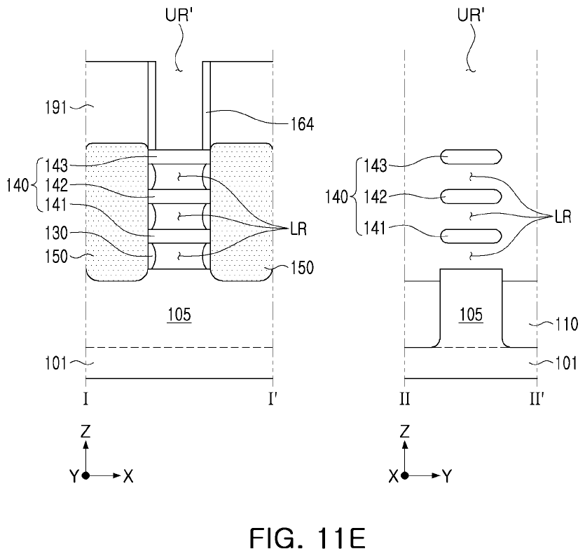

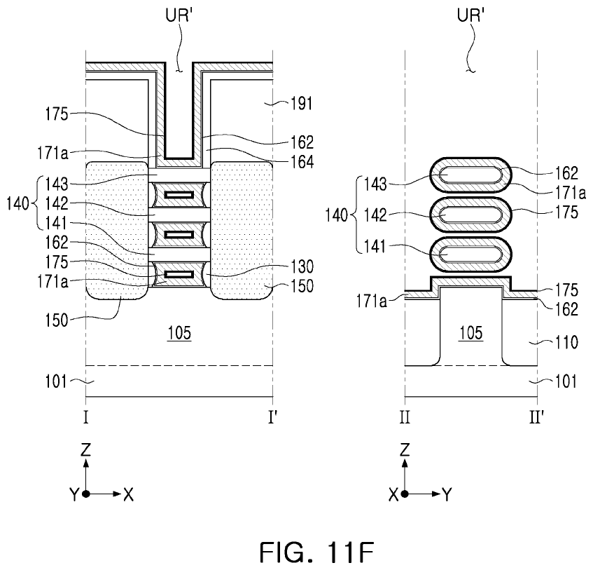

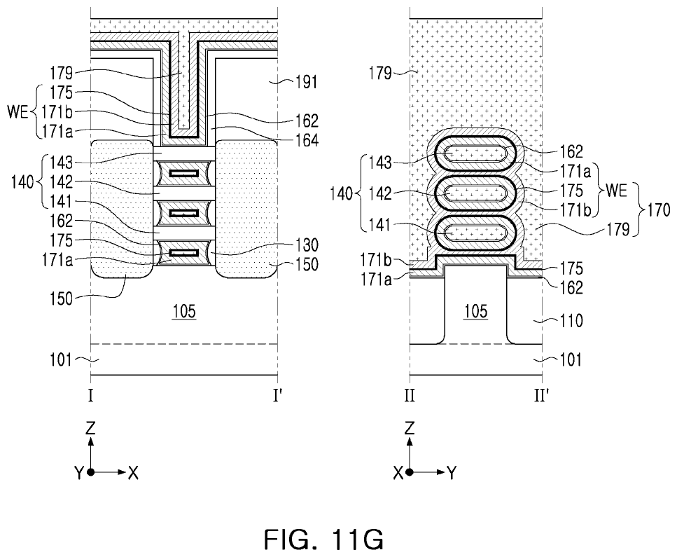

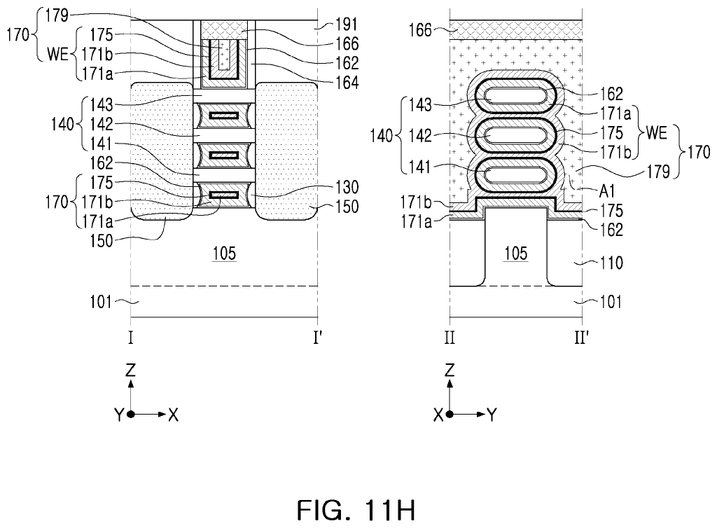

FIGS. 11A to 11H are cross-sectional views for each main process for illustrating a method of manufacturing a semiconductor device according to some implementations of the present disclosure.

Referring to FIG. 11A, sacrificial layers 120 and first to third channel layers 141, 142, and 143 may be alternately stacked on the substrate 101.

The sacrificial layers 120 may be a layer which is replaced with the gate dielectric layers 162 and the gate electrode 170 as shown in FIG. 2A through a subsequent process. The sacrificial layers 120 may be formed of a material having etch selectivity with respect to the first to third channel layers 141, 142, and 143, respectively. The first to third channel layers 141, 142, and 143 may include a material different from that of the sacrificial layers 120. The sacrificial layers 120 and the first to third channel layers 141, 142, and 143 may include, for example, a semiconductor material including at least one of silicon (Si), silicon germanium (SiGe), and germanium (Ge), but may include different substances and may or may not include impurities. For example, the sacrificial layers 120 may include silicon germanium (SiGe), and the first to third channel layers 141, 142, and 143 may include silicon (Si).

The sacrificial layers 120 and the first to third channel layers 141, 142, and 143 may be formed by performing an epitaxial growth process from the substrate 101. Each of the sacrificial layers 120 and the first to third channel layers 141, 142, and 143 may have a thickness ranging from about 1 to about 100 nm. The number of layers of the sacrificial layers 120 and the channel layers 141, 142, and 143, alternately stacked may vary in different implementations.

Referring to FIG. 11B, portions of the sacrificial layers 120, the first to third channel layers 141, 142, and 143, and the substrate 101 may be removed to form an active pattern 105, and a device isolation layer 110 may be formed.

A fin-type active structure may include sacrificial layers 120 and first to third channel layers 141, 142, and 143, alternately stacked with each other, the fin-type active structure further including an active pattern 105 formed to protrude from the substrate 101 by removing a portion of the substrate 101. The fin-type active structure may be formed in a form of a line extending in a first direction (e.g., X-direction). A device isolation layer 110 may be formed by burying an insulating material and then partially removing the insulating material so that an active pattern 105 protrudes, in a region in which a portion of the substrate 101 has been removed. An upper surface of the device isolation layer 110 may be formed to be lower than an upper surface of the active pattern 105.

Referring to FIG. 11C, a dummy gate structure DS and gate spacers 164 may be formed on the fin-type active structure.

As shown in FIG. 11C through a subsequent process, the dummy gate structure DS may be a sacrificial structure formed in a region in which the gate dielectric layers 162 and the gate electrode 170 are disposed above the channel structure 140. The dummy gate structure DS includes first and second sacrificial gate patterns 202 and 204 and a mask pattern 206, sequentially stacked. The first and second sacrificial gate patterns 202 and 204 may be patterned using the mask pattern 206. The first and second sacrificial gate patterns 202 and 204 may be an insulating layer and a conductive layer, respectively, but the present disclosure is not limited thereto, and the first and second sacrificial gate patterns 202 and 204 may be formed of one layer. For example, the first sacrificial gate pattern 202 may include silicon oxide, and the second sacrificial gate pattern 205 may include polysilicon. The mask pattern 206 may include silicon oxide and/or silicon nitride. The dummy gate structure DS may have a line shape intersecting the fin-type active structures and extending in one direction. For example, the sacrificial gate structure SS may extend in a second direction (e.g., Y-direction).

Gate spacers 164 may be formed on both sidewalls of the dummy gate structure DS. The gate spacers 164 may be formed of a low dielectric constant material, and may include, for example, at least one of SiO, SiN, SiCN, SiOC, SiON, and SiOCN.

Referring to FIG. 11D, on the outside of the dummy gate structure DS, a portion of the exposed sacrificial layers 120 and the first to third channel layers 141, 142, and 143 may be removed to form recess regions, internal spacers 130, and source/drain patterns 150 filling the recess regions.

First, using the dummy gate structure DS and the gate spacers 164 as a mask, the exposed sacrificial layers 120 and the first to third channel layers 141, 142, and 143 may be removed to form recess regions. As a result, the first to third channel layers 141, 142, and 143 may provide a channel structure 140 with a length defined in a first direction (e.g., X-direction).

Next, a portion of the sacrificial layers 120 may be removed. The sacrificial layers 120 may be selectively etched with respect to the channel structure 140 using, for example, a wet etching process, and may be removed to a predetermined depth from the side surface in the first direction (e.g., X-direction). The sacrificial layers 120 may have side surfaces which are concave inwardly by etching side surfaces of the sacrificial layers 120 as described above. However, the shape of the side surfaces of the sacrificial layers 120 is not limited to that shown. Next, internal spacers 130 may be formed in the region in which the sacrificial layers 120 are partially removed. The internal spacers 130 may be formed of the same material as the gate spacers 164, but the present disclosure is not limited thereto. For example, the internal spacers 130 may include at least one of SiN, SiCN, SiOCN, SiBCN, and SiBN.

Next, source/drain patterns 150 may be formed by being grown from an upper surface of the active pattern 105 and side surfaces of the channel structure 140 by, for example, a selective epitaxial process. The source/drain patterns 150 may include impurities through in-situ doping, and may include a plurality of layers having different doping elements and/or doping concentrations.

Referring to FIG. 11E, after forming a first interlayer insulating layer 191, the sacrificial layers 120 and the dummy gate structure DS may be removed.

The first interlayer insulating layer 191 may be formed by forming an insulating film covering the dummy gate structure DS and the source/drain patterns 150 and performing a planarization process.

The sacrificial layers 120 and the dummy gate structure DS may be removed selectively with respect to the gate spacers 164, the interlayer insulating layer 190, and the channel structure 140. First, the dummy gate structure DS may be removed to form an upper gap region UR, and then the sacrificial layers 120 exposed through the upper gap region UR may be removed to form lower gap regions LR. For example, when the sacrificial layers 120 include silicon germanium (SiGe) and the channel structures 140 include silicon (Si), the sacrificial layers 120 may be selectively removed by performing a wet etching process using peracetic acid as an etchant. During the removal process, the source/drain patterns 150 may be protected by the interlayer insulating layer 190 and internal spacers 130.

During the removal process, the source/drain patterns 150 may be protected by the interlayer insulating layer 190 and internal spacers 130.

First, referring to FIG. 11F, gate dielectric layers 162 may be formed, first work function metal layers 171a may be formed to a uniform thickness, and surfaces of the first work metal layers 171a may be oxidized to form a work function adjusting layer 175 containing oxygen.

The gate dielectric layers 162 and the first work function metal layers 171a may be sequentially formed conformally on inner surfaces of the upper gap region UR and the lower gap region LR. For example, the first work function metal layers 171a may be formed to a uniform thickness using thermal atomic layer deposition. The work function adjusting layer 175 may be obtained by heat treating a surface of the first work function metal layer 171a in an oxygen atmosphere. For example, the first work function metal layers 171a may include TiN. The work function adjusting layer 175 may include TiON. For example, the work function adjusting layer 175 may have an oxygen concentration of 1 atom % or more.

Referring to FIG. 11G, a second work function metal layer 171b may be formed on the work function adjusting layer 175, and a filling electrode 179 may be formed may be formed in the remaining space of the upper gap region UR and the lower gap region LR to provide a gate electrode 170.

In some implementations, the second work function metal layer 171b may include the same material as the first work function metal layers 171a. For example, the second work function metal layers 171b may include TiN. The second work function metal layer 171b may be formed conformally on the work function adjusting layer 175 using a thermal ALD method. In some example implementations, the second work function metal layers 171b may include a material different from the material of the first work function metal layer 171a. For example, the first work function metal layers 171a may include TiN, and the second work function metal layers 171b may include TiAlC, TiAlN, WN, or MoN.

Referring to FIG. 11H, after recessing a gate electrode 170, a gate cap layer 166 may be formed in the space, and then formed to cover the first interlayer insulating layer 191, and then a planarization process may be performed again.

The recess process of the gate electrode 170 may be performed by etch backing, and a gate electrode material located on a first filling insulating layer 1911 may be removed through an etch back process or a separate polishing process. After the planarization process, a second interlayer insulating layer 192 may be formed, contact holes opening the source/drain patterns 150 may be formed through the first and second interlayer insulating layers 191 and 192, and a conductive material may be formed by filling a conductive material within the contact holes. In this way, the semiconductor device 100 shown in FIG. 2A can be manufactured.

As set forth above, in the above-described example implementations, a threshold voltage may be lowered by introducing oxygen surface treatment in a process of forming a multilayer work function electrode pattern, and using this, a plurality of transistors with widely varying threshold voltages may be implemented.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The various and advantageous advantages and effects of the present disclosure are not limited to the above description, and may be more easily understood in the course of describing the specific implementations of the present disclosure. While example implementations have been shown and described above, it will be apparent to those skilled in the art that modifications and variations could be made without departing from the scope of the present disclosure, as defined by the appended claims.

What is claimed is:

1. A semiconductor device, comprising:
a substrate including an active pattern extending in a first direction;
a plurality of channel layers disposed on the active pattern and spaced apart from each other in a direction perpendicular to an upper surface of the substrate;
a gate structure extending in a second direction intersecting the active pattern on the substrate, and the gate structure surrounding the plurality of channel layers; and
a plurality of source/drain patterns disposed on both sides of the gate structure and connected to the plurality of channel layers,
wherein the gate structure includes
a gate dielectric layer on the plurality of channel layers;
a multilayer work function electrode pattern on the gate dielectric layer, and
a filling electrode on the multilayer work function electrode pattern, and
wherein the multilayer work function electrode pattern includes at least one work function adjusting layer having a higher oxygen concentration than an oxygen concentration of other layers.

2. The semiconductor device of claim 1, wherein
the multilayer work function electrode pattern comprises a first work function metal layer and a second work function metal layer on the first work function metal layer, and
the work function adjusting layer is disposed between the first and second work function metal layers.

3. The semiconductor device of claim 2, wherein the first and second work function metal layers comprise a same material.

4. The semiconductor device of claim 3, wherein the first and second work function metal layers comprise TiN, and the work function adjusting layer comprises TiON.

5. The semiconductor device of claim 2, wherein the first and second work function metal layers comprise different materials.

6. The semiconductor device of claim 5, wherein the first work function metal layer comprises TiN, the second work function metal layer comprises TiAlN, WN, or MoN, and the work function adjusting layer comprises TiON.

7. The semiconductor device of claim 2, wherein the multilayer work function electrode pattern comprises an additional work function adjusting layer containing fluorine (F).

8. The semiconductor device of claim 1, wherein the multilayer work function electrode pattern comprises a plurality of work function metal layers, and the work function adjusting layer comprises a plurality of work function adjusting layers between the plurality of work function metal layers.

9. The semiconductor device of claim 8, wherein the plurality of work function metal layers comprise at least one work function metal layer, formed of a material different from a material of other work function metal layers.

10. The semiconductor device of claim 1, wherein the multilayer work function electrode pattern comprises one work function metal layer, and the at least one work function adjusting layer comprises a work function adjusting layer disposed on the work function metal layer.

11. The semiconductor device of claim 1, further comprising:
an interfacial insulating layer between the plurality of channel layers and the gate dielectric layer.

12. A semiconductor device, comprising:
a first transistor and a second transistor on a substrate,
wherein each of the first transistor and the second transistor includes
an active pattern on the substrate,
a plurality of channel layers spaced apart from each other on the active pattern in a direction perpendicular to an upper surface of the substrate, and
a gate dielectric layer and a gate electrode surrounding the channel layers, and sequentially stacked on the plurality of channel layers,
wherein the gate dielectric layer of the first transistor includes a first work function metal layer and a first work function adjusting layer on the first work function metal layer, and the gate electrode of the second transistor includes a second work function metal layer,
wherein the first and second work function metal layers include a same material, and the first work function adjusting layer includes an oxide of the same material, and
wherein a threshold voltage of the first transistor is lower than a threshold voltage of the second transistor.

13. The semiconductor device of claim 12, wherein the first and second work function metal layers comprise TiN, and the first work function adjusting layer comprises TiON.

14. The semiconductor device of claim 12, wherein the first work function metal layer of the first transistor comprises two first work function metal layers, and the first work function adjusting layer is disposed between the two first work function metal layers.

15. The semiconductor device of claim 14, wherein a thickness of the second work function metal layer is substantially the same as a total thickness of the two first work function metal layers and the first work function adjusting layer.

16. The semiconductor device of claim 12, further comprising:
a third transistor on the substrate,
wherein the third transistor includes the active pattern, the plurality of channel layers on the active pattern, and the gate dielectric layer and the gate electrode, sequentially stacked on the plurality of channel layers,
the gate electrode of the third transistor includes a third work function metal layer and a second work function adjusting layer on the third work function metal layer, and
the third work function metal layer includes the same material as the first and second work function metal layers, and the second work function adjusting layer includes the same material and at least one compound of boron and carbon, and
a threshold voltage of the third transistor is higher than the threshold voltage of the second transistor.

17. The semiconductor device of claim 16, wherein the first to third work function metal layers comprise TiN, the first work function adjusting layer comprises TiON, and the second work function adjusting layer comprises TiN containing boron and carbon.

18. The semiconductor device of claim 16, wherein the third work function metal layer of the third transistor comprises a plurality of third work function metal layers, and the second work function adjusting layer is disposed between the plurality of third work function metal layers.

19. A semiconductor device, comprising:
a first transistor and a second transistor on a substrate,
wherein each of the first transistor and the second transistor includes
an active pattern on the substrate,
a plurality of channel layers spaced apart from each other on the active pattern in a direction perpendicular to an upper surface of the substrate, and
a gate dielectric layer and a gate electrode surrounding the plurality of channel layers, and sequentially stacked on the channel layers,
wherein the gate electrode of each of the first transistor and the second transistor includes a first work function metal layer, a work function adjusting layer on the first work function metal layer, and a second work function metal layer on the work function adjusting layer,
wherein the first and second work function metal layers include a same material, and the first work function adjusting layer includes an oxide of the same material, and
wherein the gate dielectric layer of each of the first transistor and the second transistor includes different dielectric materials, and the first transistor and the second transistor have different threshold voltages.

20. The semiconductor device of claim 19, wherein the first and second work function metal layers comprise TiN, and the work function adjusting layer comprises TiON.
